(19) United States
(12) Patent Application Publication
(10) Pub. No.: US 2024/0429203 A1
(43) Pub. Date: Dec. 26, 2024

(54) SEMICONDUCTOR PACKAGE AND FABRICATING METHOD OF SEMICONDUCTOR PACKAGE

(71) Applicant: Samsung Electronics Co., Ltd., Suwon-si (KR)

(72) Inventors: Jing Cheng LIN, Suwon-si (KR); Youngkun JEE, Suwon-si (KR)

(73) Assignee: Samsung Electronics Co., Ltd., Suwon-si (KR)

(21) Appl. No.: 18/427,470

(22) Filed: Jan. 30, 2024

(30) Foreign Application Priority Data
Jun. 21, 2023 (KR) 10-2023-0079815

(51) Int. Cl. H01L 25/065; H01L 23/00; H01L 23/31; H01L 23/498; H01L 23/538

(52) U.S. Cl. CPC H01L 25/0655; H01L 23/3121; H01L 23/49811; H01L 23/5383; H01L 23/5385; H01L 24/16; H01L 24/32; H01L 2224/16235; H01L 2224/32225

(57) ABSTRACT

Provided is a semiconductor package including a first redistribution structure, a second redistribution structure on the first redistribution structure, a plurality of semiconductor chips on an upper surface of the second redistribution structure, a bridge chip on a lower surface of the second redistribution structure, and a first molding layer between the first redistribution structure and the second redistribution structure and adjacent to the bridge chip, wherein the first molding layer is between the bridge chip and the first redistribution structure.

### CROSS-REFERENCE TO RELATED APPLICATION

This application is based on and claims priority to Korean Patent Application No. 10-2023-0079815, filed on Jun. 21, 2023, in the Korean Intellectual Property Office, the disclosure of which is incorporated by reference herein in its entirety.

### BACKGROUND

Embodiments of the present disclosure relate to a semiconductor package and a fabricating method thereof, and more particularly, to a semiconductor package including a bridge chip and a fabricating method thereof.

According to the development of the electronics industry and the needs of users, electronic devices are becoming smaller and lighter. As the electronic devices become smaller and lighter, the semiconductor package used in the electronic devices is also becoming smaller and lighter and requires high reliability together with high performance and high capacity. According to the high performance and the high capacity of the semiconductor package, the power consumption is increasing in the semiconductor package. Accordingly, the importance of the structure of the semiconductor package for responding to the size/performance of the semiconductor package and more stably supplying power to the semiconductor package is increasing.

### SUMMARY

One or more embodiments provide a semiconductor package having improved structural reliability and a fabricating method thereof.

According to an aspect of an embodiment, there is provided a semiconductor package including a first redistribution structure, a second redistribution structure on the first redistribution structure, a plurality of semiconductor chips on an upper surface of the second redistribution structure, a bridge chip on a lower surface of the second redistribution structure, and a first molding layer between the first redistribution structure and the second redistribution structure and adjacent to the bridge chip, wherein the first molding layer is between the bridge chip and the first redistribution structure.

According to another aspect of an embodiment, there is provided a semiconductor package including a first redistribution structure, a second redistribution structure on the first redistribution structure, a plurality of semiconductor chips on an upper surface of the second redistribution structure, a bridge chip on a lower surface of the second redistribution structure, a passive device spaced apart from the bridge chip in a horizontal direction and on the lower surface of the second redistribution structure, a first molding layer between the first redistribution structure and the second redistribution structure and adjacent to the bridge chip and the passive device, a plurality of conductive posts arranged in the first molding layer and spaced apart from the bridge chip and the passive device in the horizontal direction, and a second molding layer on the upper surface of the second redistribution structure and adjacent to the plurality of semiconductor chips, wherein the first molding layer is between the bridge chip and the first redistribution structure and between the passive device and the first redistribution structure.

According to another aspect of an embodiment, there is provided a semiconductor package including a first redistribution structure including a passivation layer, an under bump metallurgy (UBM) layer on a portion of a lower surface of the passivation layer, and a conductive layer in contact with the UBM layer and exposed to an upper surface opposite to the lower surface of the passivation layer, a second redistribution structure including at least one redistribution insulating layer, a plurality of conductive line patterns in the at least one redistribution insulating layer and extending in a horizontal direction, and a plurality of conductive vias in the at least one redistribution insulating layer and extending in a vertical direction perpendicular to the horizontal direction, a plurality of semiconductor chips on an upper surface of the second redistribution structure, a bridge chip on a lower surface of the second redistribution structure and electrically connecting at least two of the plurality of semiconductor chips, a passive device on the lower surface of the second redistribution structure and spaced apart from the bridge chip in the horizontal direction, a first molding layer between the first redistribution structure and the second redistribution structure and adjacent to a side surface of the bridge chip and a side surface of the passive device, a plurality of conductive posts in the first molding layer and spaced apart from the bridge chip and the passive device in the horizontal direction, and a second molding layer on the upper surface of the second redistribution structure and adjacent to the plurality of semiconductor chips, wherein the first molding layer is between the bridge chip and the first redistribution structure and between the passive device and the first redistribution structure.

### BRIEF DESCRIPTION OF THE DRAWINGS

Embodiments will be more clearly understood from the following detailed description taken in conjunction with the accompanying drawings in which:

FIG. 1A is a plan view illustrating a semiconductor package according to an embodiment, and FIG. 1B is a cross-sectional view of the semiconductor package of FIG. 1A taken along line A-A′;

FIG. 2 is a cross-sectional view illustrating a semiconductor package according to an embodiment;

FIG. 3 is a cross-sectional view illustrating a semiconductor package according to an embodiment;

FIG. 4 is a cross-sectional view illustrating a semiconductor package according to an embodiment;

FIG. 5 is a cross-sectional view illustrating a semiconductor package according to an embodiment;

FIG. 6 is a cross-sectional view illustrating a semiconductor package according to an embodiment; and

FIGS. 7A, 7B, 7C, 7D, 7E, 7F, 7G, 7H, 7I, 7J, and 7K are cross-sectional views illustrating a method of fabricating a semiconductor package, according to an embodiment.

### DETAILED DESCRIPTION OF THE EMBODIMENTS

Hereinafter, embodiments are described in detail with reference to the accompanying drawings. The same reference numerals denote the same elements in the drawings, and redundant descriptions on the same elements are omitted.

Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

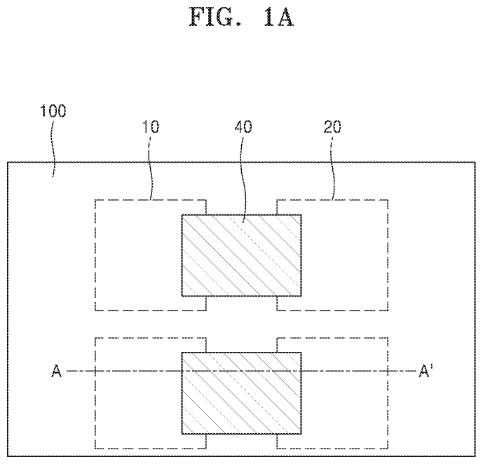

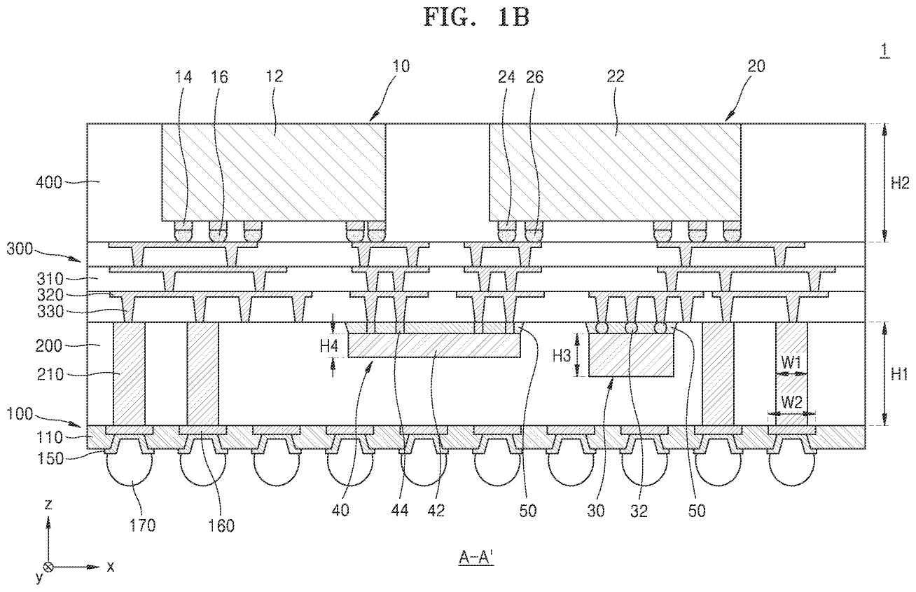

FIG. 1A is a plan view illustrating a semiconductor package according to an embodiment, and FIG. 1B is a cross-sectional view of the semiconductor package of FIG. 1A taken along line A-A′. For convenience of explanation, only a first semiconductor chip 10, a second semiconductor chip 20, a bridge chip 40, and a first redistribution structure 100 are illustrated in FIG. 1A.

Referring to FIGS. 1A and 1B, a semiconductor package 1 may include the first semiconductor chip 10, the second semiconductor chip 20, a first device 30, the bridge chip 40, the first redistribution structure 100, a first molding layer 200, a second redistribution structure 300, and a second molding layer 400. The semiconductor package 1 may include a package having a fan-out structure. A size of the first redistribution structure 100 and the second redistribution structure 300 may be larger than a size of the first semiconductor chip 10 and the second semiconductor chip 20. The size of the first redistribution structure 100 and the second redistribution structure 300 may be the same as a size of the semiconductor package 1.

Herein, a direction parallel to a main surface of the first redistribution structure 100 may be referred to as a horizontal direction (X direction and/or Y direction), and a direction perpendicular to the horizontal direction (X direction and/or Y direction) may be referred to as a vertical direction (Z direction).

In addition, among the two surfaces spaced apart in the vertical direction (Z direction), the surface further separated from an external connection terminal 170 may be referred to as an upper surface of a component, and the surface opposite to the upper surface may be referred to as a lower surface of the component.

The first redistribution structure 100 may include a passivation layer 110, an under bump metallurgy (UBM) layer 150, and a conductive layer 160. For example, the passivation layer 110 may have a single-layer structure formed of one layer. In another embodiment, the passivation layer 110 may have a multi-layer structure. The passivation layer 110 may cover an entire exposed lower surface and an entire side surface of the conductive layer 160 and may expose an upper surface of the conductive layer 160. In addition, a portion of the lower surface of the passivation layer 110 may be covered by the UBM layer 150.

The passivation layer 110 may include an insulating material, for example, silicon oxide, silicon nitride, phosphosilicate glass (PSG), borophosphosilicate glass (BPSG), fluorosilicate glass (FSG), and a combination thereof.

The UBM layer 150 may include a UBM pad positioned on the lower surface of the passivation layer 110 and a UBM via vertically penetrating at least a portion of the passivation layer 110 and electrically connecting the UBM pad to the conductive layer 160. In an embodiment, the UBM via may have a truncated cone cup shape in which the central space is partially empty but may have a truncated cone shape in which the central space is filled depending on embodiments. In an embodiment, the UBM pad may have an annular shape in which the central space is empty but may have a coin shape in which the central space is filled depending on embodiments. The UBM layer 150 may electrically connect the conductive layer 160 with other components of the semiconductor package 1 such as an external connection terminal 170 described below. In addition, the UBM layer 150 may prevent the external connection terminal 170 from cracking due to the thermal shock between the external connection terminal 170 and the first redistribution structure 100, to thereby improve the reliability of the semiconductor package 1. The UBM layer 150 may include a conductive material, for example, copper (Cu), aluminum (Al), silver (Ag), gold (Au), tungsten (W), titanium (Ti), and a combination thereof.

The conductive layer 160 may be arranged in the passivation layer 110, and the upper surface of the conductive layer 160 may be exposed from the upper surface of the passivation layer 110. The conductive layer 160 may be positioned under a plurality of conductive posts 210, and the upper surface of the conductive layer 160 may be provided on and bonded to a lower surface of the plurality of conductive posts 210. The conductive layer 160 may be a plurality of conductive patterns that are spaced apart in the first horizontal direction (X direction) or the second horizontal direction (Y direction). Although, in FIG. 1B, the conductive layer 160 is shown as single layered conductive patterns that are arranged at a single vertical level, the conductive layer 160 may be provided as a multilayered conductive pattern that is arranged at different vertical levels depending on embodiments. The conductive layer 160 may electrically connect different components of the semiconductor package 1, such as the plurality of conductive posts 210 and the UBM layer 150, with each other. The conductive layer 160 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), and an alloy thereof but is not limited thereto.

The semiconductor package 1 may further include the external connection terminal 170 that is positioned on the lower surface of the UBM layer 150. The external connection terminal 170 may be configured to connect the first redistribution structure 100 and an external device electrically and physically. In an embodiment, the external connection terminal 170 may include, for example, a solder ball, a conductive bump, and a flip-chip connection structure having a grid array such as a pin grid array, a ball grid array, and a land grid array. The external connection terminal 170 may be electrically connected to the UBM layer 150 of the first redistribution structure 100 and may be electrically connected to the external device such as a module substrate and a system board.

As shown in FIG. 1B, the external connection terminal 170 may not be directly bonded and connected to the conductive post 210 surrounding the bridge chip 40, but the first redistribution structure 100 may be positioned between the plurality of conductive posts 210 and the plurality of external connection terminals 170. Because the scale of the line width of the conductive layer 160 may be less than that of the external connection terminal 170, the first redistribution structure 100 including the conductive layer 160 is formed between the plurality of conductive posts 210 and the external connection terminal 170, to thereby enable the fabricating process to be much finer. In addition, when the first redistribution structure 100 is formed between the plurality of conductive posts 210 and the external connection terminals 170, a larger number of external connection terminals 170 may be arranged on the first redistribution structure 100 as compared with a related embodiment where external connection terminals 170 make direct contact with the plurality of conductive posts 210 and are bonded and connected to the plurality of conductive posts 210. As a number of external connection terminals 170 in the semiconductor package 1 increases, the stability of the power supply to the semiconductor package 1 increases.

The first molding layer 200 and the plurality of conductive posts 210 may be arranged on the first redistribution structure 100. The first molding layer 200 may cover the first device 30, the bridge chip 40, and the plurality of conductive posts 210 on the first redistribution structure 100. The first molding layer 200 may sufficiently seal the first device 30 and the bridge chip 40 between the first redistribution structure 100 and the second redistribution structure 300. The first molding layer 200 may cover the side surfaces of the plurality of conductive posts 210 between the first redistribution structure 100 and the second redistribution structure 300.

The first molding layer 200 may include, for example, a thermosetting resin, a thermoplastic resin, a UV curable resin, and a combination thereof. The first molding layer 200 may include, for example, an epoxy resin, a silicon resin, and a combination thereof. The first molding layer 200 may include, for example, an epoxy mold compound (EMC).

The plurality of conductive posts 210 may be positioned between the first redistribution structure 100 and the second redistribution structure 300 in the first molding layer 200. The plurality of conductive posts 210 may provide an electrical connection path between the first redistribution structure 100 and the second redistribution structure 300. The plurality of conductive posts 210 may include a conductive material including, for example, copper (Cu), aluminum (Al), silver (Ag), gold (Au), tungsten (W), titanium (Ti), and a combination thereof.

The plurality of conductive posts 210 may have an upper surface and a lower surface spaced apart from each other in the vertical direction (Z direction). The upper surface of the plurality of conductive posts 210 may be coplanar with the upper surface of the first molding layer 200, and the lower surface of the plurality of conductive posts 210 may be coplanar with the lower surface of the first molding layer 200. The plurality of conductive posts 210 may be in direct contact with the conductive layer 160 exposed on the upper surface of the passivation layer 110. For example, the lower surfaces of the plurality of conductive posts 210 may be bonded and connected to the upper surface of the conductive layer 160.

Each of the plurality of conductive posts 210 may have, for example, a cylindrical shape. In this case, the diameters of the plurality of conductive posts 210 may be maintained constant in the vertical direction (Z direction). In another embodiment, the plurality of conductive posts 210 may have tapered shapes having diameters that vary in the vertical direction (Z direction).

The second redistribution structure 300 may be positioned on the first molding layer 200. The second redistribution structure 300 may include one or more redistribution insulating layers 310, a plurality of conductive line patterns 320, and a plurality of conductive vias 330.

The redistribution insulating layers 310 may be stacked in the vertical direction (Z direction). The redistribution insulating layer 310 may include an insulating material, such as a photo-imageable dielectric (PID) resin, and may further include photosensitive polyimide and/or inorganic fillers.

The plurality of conductive line patterns 320 and the plurality of conductive vias 330 may be provided as the conductive pattern, and the conductive pattern may be positioned on at least one of an upper surface and a lower surface of the redistribution insulating layer 310. The plurality of conductive line patterns 320 may be arranged to extend in the horizontal direction (X direction and/or Y direction) in the redistribution insulating layer 310. The plurality of conductive vias 330 may penetrate at least one redistribution insulating layer 310 in the vertical direction (Z direction), to thereby contact and be electrically connected with some of the plurality of conductive line patterns 320.

In some embodiments, at least some of the plurality of conductive line patterns 320 may be integrally provided together with some of the plurality of conductive vias 330. For example, the plurality of conductive line patterns 320 and the plurality of conductive vias 330, which are in contact with the upper surface of the plurality of conductive line patterns 320, may be integrated in one body.

In some embodiments, the plurality of conductive vias 330 may have a tapered shape extending with a narrow horizontal width from the top to the bottom thereof. That is, the horizontal widths of the plurality of conductive vias 330 may narrow away from the first semiconductor chip 10.

A plurality of redistribution patterns including the plurality of conductive line patterns 320 and the plurality of conductive vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

The first semiconductor chip 10, the second semiconductor chip 20, and a second molding layer 400 may be positioned on the upper surface of the second redistribution structure 300. The first device 30, the bridge chip 40, the first molding layer 200, and the conductive post 210 may be positioned on the lower surface of the second redistribution structure 300. The first semiconductor chip 10 and the second semiconductor chip 20 may be spaced apart in the horizontal direction (X direction and/or Y direction) on the upper surface of the second redistribution structure 300. In addition, the first device 30 and the bridge chip 40 may be spaced apart in the horizontal direction (X direction and/or Y direction) on the lower surface of the second redistribution structure 300.

The first semiconductor chip 10 may include a first substrate 12 and a first chip pad 14, and the second semiconductor chip 20 may include a second substrate 22 and a second chip pad 24. Each of the first substrate 12 and the second substrate 22 may include an active surface and an inactive surface opposite to each other. The active surface may be adjacent to a lower surface of each of the first substrate 12 and the second substrate 22, and the inactive surface may be adjacent to an upper surface of each of the first substrate 12 and the second substrate 22.

In some embodiments, at least one of the first semiconductor chip 10 and the second semiconductor chip 20 may be a memory chip or a logic chip. The memory chip may include, for example, a volatile memory chip, such as a dynamic random access memory (DRAM) device and a static random access memory (SRAM) device, and a nonvolatile memory chip, such as a phase-change random access memory (PRAM) device, a magnetoresistive random access memory (MRAM) device, a ferroelectric random access memory (FeRAM) device, and a resistive random access memory (RRAM) device. In addition, the logic chip may include, for example, a microprocessor, an analog device, and a digital signal processor.

The first substrate 12 and the second substrate 22 may include an integrated circuit. The integrated circuit may be any type of integrated circuit including a memory circuit, a logic circuit, and a combination thereof. The memory circuit may include, for example, a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, and a combination thereof. The logic circuit may include, for example, a central processing unit (CPU) circuit, a graphics processing unit (GPU) circuit, a controller circuit, an application specific integrated circuit (ASIC), an application processor (AP) circuit, and a combination thereof.

In addition, the first substrate 12 and the second substrate 22 may include a semiconductor material, such as a Group IV semiconductor material, a Group III-V semiconductor material, a Group II-VI semiconductor material, and a combination thereof. The group IV semiconductor material may include, for example, silicon (Si), germanium (Ge), and a combination thereof. The Group III-V semiconductor material may include, for example, gallium arsenide (GaAs), indium phosphide (InP), gallium phosphide (GaP), indium arsenide (InAs), indium antimonide (InSb), indium gallium arsenide (InGaAs), and a combination thereof. The Group II-VI semiconductor material may include, for example, zinc telluride (ZnTe), cadmium sulfide (CdS), and a combination thereof.

The first chip pad 14 and the second chip pad 24 may be positioned on the lower surfaces of the first substrate 12 and the second substrate 22, respectively, and may extend along the lower surfaces, which are the active surfaces of the first substrate 12 and the second substrate 22, respectively. In addition, a first connection member 16 may be positioned between the first semiconductor chip 10 and the second redistribution structure 300, and a second connection member 26 may be positioned between the second semiconductor chip 20 and the second redistribution structure 300.

The first chip pad 14 may contact the first connection member 16, and the second chip pad 24 may contact the second connection member 26. Each of the first connection member 16 and the second connection member 26 may contact the conductive line pattern 320 and/or the conductive via 330 of the second redistribution structure 300. Therefore, the first connection member 16 may be provided as an electrical connection path between the first semiconductor chip 10 and the second redistribution structure 300, and the second connection member 26 may be provided as an electrical connection path between the second semiconductor chip 20 and the second redistribution structure 300.

The first chip pad 14 and the second chip pad 24 may include a conductive material, for example, copper (Cu), aluminum (Al), silver (Ag), gold (Au), tungsten (W), titanium (Ti), and a combination thereof. In addition, the first connection member 16 and the second connection member 26 may include, for example, a solder ball.

The second molding layer 400 may cover the first semiconductor chip 10 and the second semiconductor chip 20 on the second redistribution structure 300. An upper surface of the second molding layer 400 may be coplanar with an upper surface of the first semiconductor chip 10 and an upper surface of the second semiconductor chip 20.

The second molding layer 400 may include, for example, a thermosetting resin, a thermoplastic resin, a UV curable resin, and a combination thereof. The second molding layer 400 may include, for example, an epoxy resin, a silicon resin, and a combination thereof. The second molding layer 400 may include, for example, an epoxy mold compound (EMC). In some embodiments, the second molding layer 400 may include the same material as the first molding layer 200. In another embodiment, the second molding layer 400 may include a material different from that of the first molding layer 200.

The first device 30 may be positioned on the lower surface of the second redistribution structure 300. The first device 30 may include various types of passive components or various types of surface mountable components. For example, the first device 30 may be referred to as a passive device. For example, the passive components may include at least one selected from a register, a capacitor, an inductor, a thermistor, an oscillator, a ferrite bead, an antenna, a varistor, and a crystal. For example, the passive components may include a multilayer ceramic capacitor (MLCC), a low inductance chip capacitor (LICC), a land side capacitor (LSC), an integrated passive device (IPD), etc.

A third connection member 32 may be positioned between the first device 30 and the second redistribution structure 300. The first device 30 may be electrically connected to the second redistribution structure 300 through the third connection member 32. For example, the third connection member 32 may include a solder ball.

The bridge chip 40 may also be positioned on the lower surface of the second redistribution structure 300. The bridge chip 40 may be provided as an electrical connection path between the first semiconductor chip 10 and the second semiconductor chip 20 that are arranged on the second redistribution structure 300. For example, the first semiconductor chip 10 and the second semiconductor chip 20 may be electrically connected to each other through a bridge circuit in the bridge chip 40. As shown in FIG. 1A, each of the first semiconductor chip 10 and the second semiconductor chip 20 may overlap at least a portion of the bridge chip 40 in the vertical direction (Z direction).

The bridge chip 40 may include a bridge substrate 42 and the bridge circuit. The bridge chip 40 may not directly contact the first redistribution structure 100 but may be electrically and indirectly connected to the first redistribution structure 100 through the conductive post 210 and the second redistribution structure 300.

An active surface of the bridge substrate 42 may be positioned adjacent to the upper surface of the bridge substrate 42, and an inactive surface of the bridge substrate 42 may be positioned adjacent to the lower surface of the bridge substrate 42. The bridge substrate 42 may include a semiconductor material, such as a Group IV semiconductor material, a Group III-V semiconductor material, a Group II-VI semiconductor material, and a combination thereof. The group IV semiconductor material may include, for example, silicon (Si), germanium (Ge), and a combination thereof. The Group III-V semiconductor material may include, for example, gallium arsenide (GaAs), indium phosphide (InP), gallium phosphide (GaP), indium arsenide (InAs), indium antimonide (InSb), indium gallium arsenide (InGaAs), and a combination thereof. The Group II-VI semiconductor material may include, for example, zinc telluride (ZnTe), cadmium sulfide (CdS), and a combination thereof. In addition, the bridge substrate 42 may include glass or ceramic as well as the semiconductor material.

The bridge circuit may be provided in the bridge substrate 42. The bridge circuit may have a pitch corresponding to a relatively small pitch of the chip pads of the first semiconductor chip 10 and the second semiconductor chip 20. Accordingly, the specifications of the line and the space L/S in the bridge circuit may be about 2 micrometers or less, respectively. The bridge circuit may have a relatively small pitch that is less than the conductive layer 160. For example, the line width of the bridge circuit may be less than the line width of the conductive layer 160.

A fourth connection member 44 may be positioned between the bridge chip 40 and the second redistribution structure 300. The fourth connection member 44 may electrically connect the second redistribution structure 300 to the bridge chip 40. The fourth connection member 44 may contact the conductive line pattern 320 and/or the conductive via 330 of the second redistribution structure 300. For example, the fourth connection member 44 may include a conductive pillar. For example, the fourth connection member 44 may have a single cylindrical shape. Thus, the fourth connection member 44 may have a constant diameter along the vertical direction (Z direction). In another embodiment, the fourth connection member 44 may have a tapered shape in which the diameter changes along the vertical direction (Z direction). For example, the fourth connection member 44 may include a conductive material such as copper (Cu), aluminum (Al), silver (Ag), gold (Au), tungsten (W), titanium (Ti), and a combination thereof.

In another embodiment, each of the first device 30 and/or the bridge chip 40 may include a chip pad. When the first device 30 includes a chip pad, the chip pad of the first device 30 may contact with third connection member 32. In addition, when the bridge chip 40 includes a chip pad, the chip pad of the bridge chip may contact the fourth connection member 44.

The semiconductor package 1 may further include an underfill layer 50 adjacent to and surrounding the third connection member 32 and the fourth connection member 44. A gap space between the first device 30 and the second redistribution structure 300 and between the bridge chip 40 and the second redistribution structure 300 may be filled with the underfill layer 50. The underfill layer 50 may include a slant outer surface. The underfill layer 50 may include an epoxy resin or two or more silicon hybrid materials. Accordingly, the third connection member 32 and the fourth connection member 44 may contact the underfill layer 50.

The first device 30 and the bridge chip 40 may be positioned at a vertical level higher than the lower surface of the first redistribution structure 100. In addition, the first device 30 and the bridge chip 40 may be spaced apart from the upper surface of the first redistribution structure 100 in the vertical direction (Z direction). For example, the first device 30 and the bridge chip 40 may be spaced apart from the first redistribution structure 100. For example, the first molding layer 200 may be positioned between the first device 30 and the first redistribution structure 100 and between the bridge chip 40 and the first redistribution structure 100.

Therefore, a first height H1 of the first molding layer 200 on which the first device 30 and the bridge chip 40 are positioned may be lower than a second height H2 of the second molding layer 400 on which the first semiconductor chip 10 and the second semiconductor chip 20 are positioned. Accordingly, the total height (or thickness) of the semiconductor package 1 may be reduced.

In addition, the first device 30 may have a third height H3 and the bridge chip 40 may have a fourth height H4 in the first molding layer 200. The third height H3 and the fourth height H4 may be different from each other. In another embodiment, the third height H3 and the fourth height H4 may be the same.

In addition, the conductive post 210 may have a first horizontal width W1 in the horizontal direction (X direction and/or Y direction), and the conductive layer 160 may have a second horizontal width W2 in the horizontal direction (X direction and/or Y direction). The first horizontal width W1 may be smaller than the second horizontal width W2.

In the conventional semiconductor package, a first device and a bridge chip are positioned on the lower surface of a first redistribution structure or in the semiconductor chip. Thus, the size of the components in the conventional semiconductor package may be determined according to the size of the first device and the bridge chip, and there may be many limitations on the fabricating process for the related semiconductor package.

However, the first device 30 and the bridge chip 40 may be positioned on the lower surface of the second redistribution structure 300 in the semiconductor package 1 according to an embodiment, to thereby reduce the limitations on the component size of the semiconductor package 1. Accordingly, the limitations on the fabricating process for the semiconductor package 1 may be reduced. In addition, since the first device 30 and the bridge chip 40 are positioned in the first molding layer 200 and the height of the first molding layer 200 decreases, the resistance to warpage may increase to thereby improve the physical reliability of the semiconductor package 1.

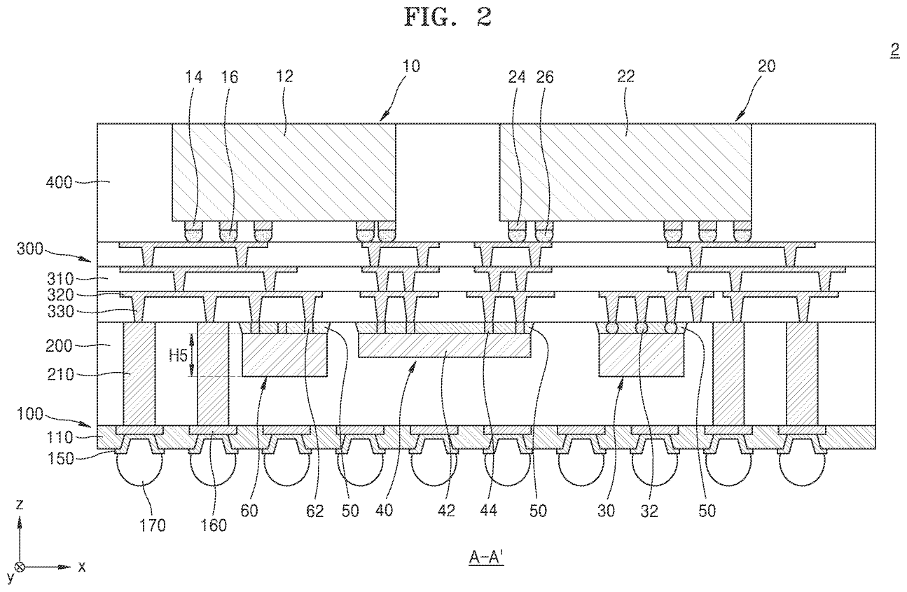

FIG. 2 is a cross-sectional view illustrating a semiconductor package according to an embodiment. The descriptions with reference to FIG. 2 are given together with reference to FIGS. 1A and 1B.

Referring to FIG. 2, a semiconductor package 2 according to another embodiment may include a first semiconductor chip 10, a second semiconductor chip 20, a first device 30, a bridge chip 40, a second device 60, a first redistribution structure 100, a first molding layer 200, a second redistribution structure 300, and a second molding layer 400. The first semiconductor chip 10, the second semiconductor chip 20, the first device 30, the bridge chip 40, the first redistribution structure 100, the first molding layer 200, the second redistribution structure 300, and the second molding layer 400 in the semiconductor package 2 in FIG. 2 may have substantially the same structures as the first semiconductor chip 10, the second semiconductor chip 20, the first device 30, the bridge chip 40, the first redistribution structure 100, the first molding layer 200, the second redistribution structure 300, and the second molding layer 400 in the semiconductor package 1 in FIG. 1B.

The second device 60 may be positioned on the lower surface of the second redistribution structure 300. The second device 60 may be spaced apart from the first device 30 and the bridge chip 40 in the horizontal direction (X direction and/or Y direction). Each of the first device 30, the bridge chip 40, and the second device 60 may be enclosed by the first molding layer 200.

For example, the second device 60 may include a chiplet. The chiplet may include a plurality of IP blocks, and the plurality of IP blocks may perform different functions. Each of the plurality of IP blocks may include a plurality of integrated circuits. In another embodiment, the second device 60 may include an active device. In another embodiment, the second device 60 may include a semiconductor chip. For example, the second device 60 may include an input/output chip (I/O chip) and a power management chip. The power management chip may include a power management integrated circuit (PMIC).

The second device 60 may be spaced apart from the first redistribution structure 100 in the vertical direction (Z direction). For example, the first molding layer 200 may be positioned between the second device 60 and the first redistribution structure 100.

In addition, the second device 60 may have a fifth height H5 from an upper surface thereof to a lower surface thereof. The third to fifth heights H3, H4, and H5 may be different from one another. In another embodiment, at least two of the third to fifth heights H3, H4, and H5 may be the same.

A fifth connection member 62 may be positioned between the second device 60 and the second redistribution structure 300. The second device 60 may be electrically connected to the second redistribution structure 300 through the fifth connection member 62. The fifth connection member 62 may contact the conductive line pattern 320 and/or the conductive via 330 of the second redistribution structure 300. A plurality of fifth connection members 62 may also be enclosed by the underfill layer 50.

In another embodiment, the second device 60 may include a chip pad. When the second device 60 includes a chip pad, the chip pad may contact the fifth connection member 62.

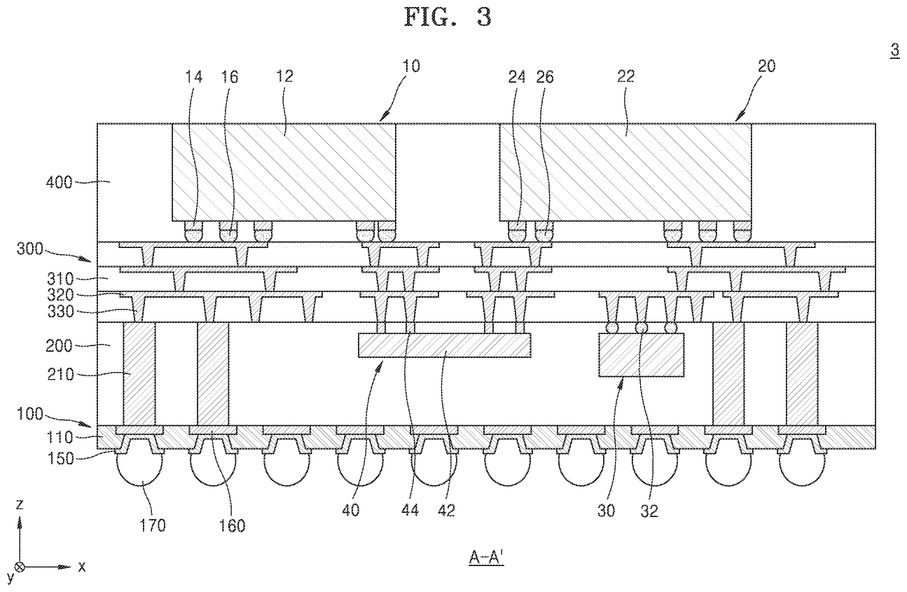

FIG. 3 is a cross-sectional view illustrating a semiconductor package according to an embodiment. The descriptions of FIG. 3 are given together with reference to FIGS. 1A and 1B.

Referring to FIG. 3, a semiconductor package 3 according to an embodiment may have substantially the same structures as the semiconductor package 1 in FIGS. 1A and 1B, except that no underfill layer 50 is provided and the third connection member 32 and the fourth connection member 44 are not surrounded by the underfill layer 50. For example, the third connection member 32 and the fourth connection member 44 may be in direct contact with the first molding layer 200.

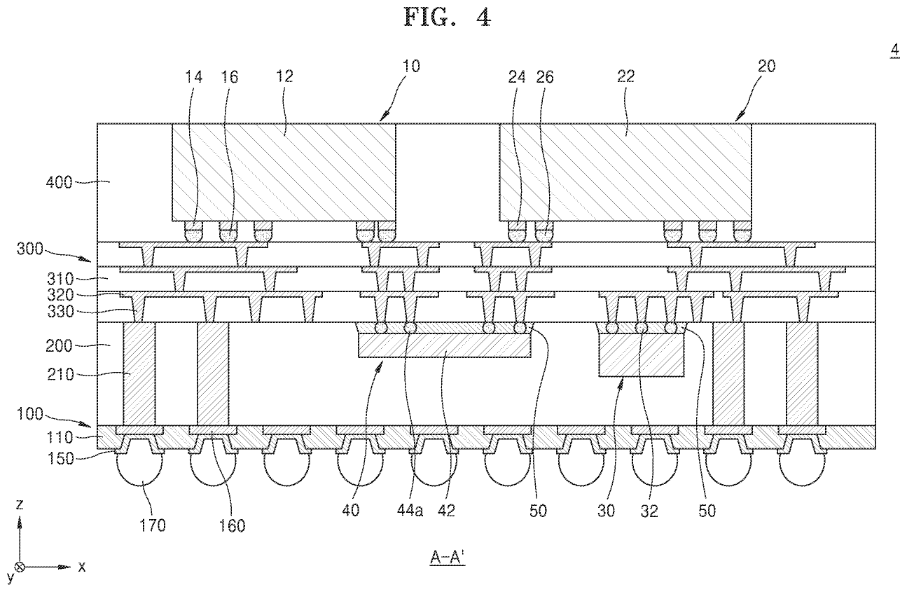

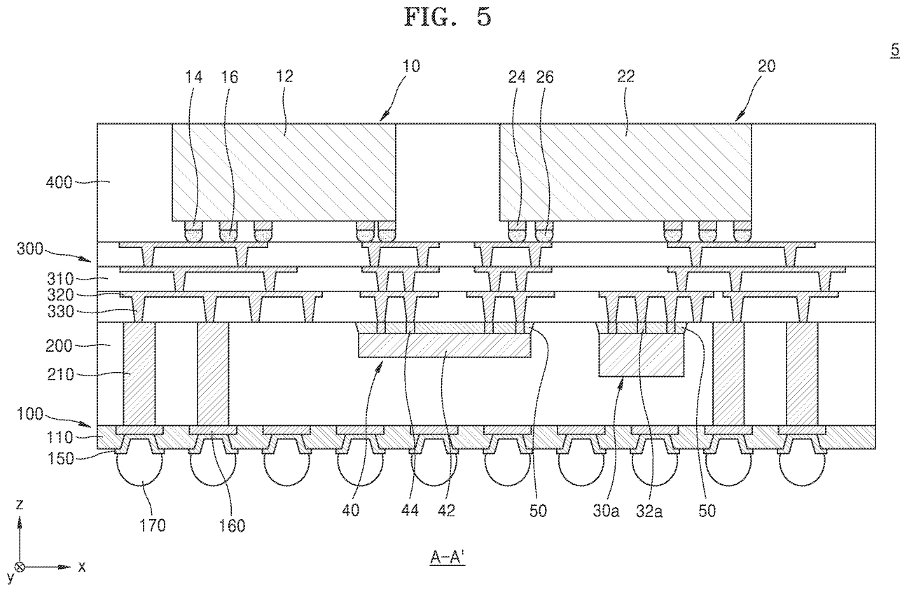

FIGS. 4 and 5 are cross-sectional views illustrating semiconductor packages according to embodiments. The descriptions of FIGS. 4 and 5 are given together with reference to FIGS. 1A and 1B.

Referring to FIGS. 4 and 5, a semiconductor package 4 in FIG. 4 may include a fourth connection member 44a having a solder ball, and a semiconductor package 5 in FIG. 5 may include a third connection member 32a having a conductive pillar. The conductive pillar may have a single cylindrical shape. In this case, a plurality of conductive pillars may have a constant diameter in the vertical direction (Z direction). In another embodiment, the conductive pillar may have a tapered shape having a diameter that varies in the vertical direction (Z direction). For example, the third and fourth connection members 32a and 48a may include a conductive material such as copper (Cu), aluminum (Al), silver (Ag), gold (Au), tungsten (W), titanium (Ti), and a combination thereof. The third connecting members 32a and the fourth connecting members 44a may be variously modified.

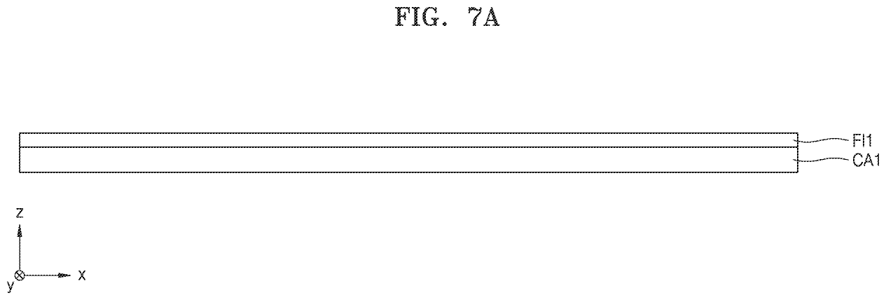

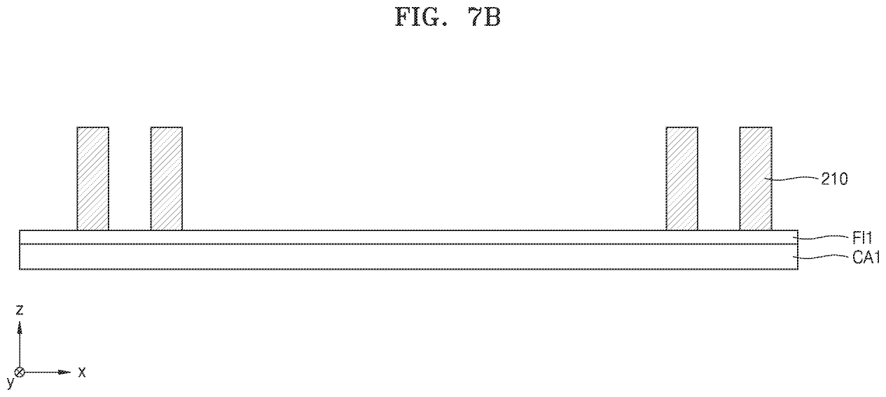

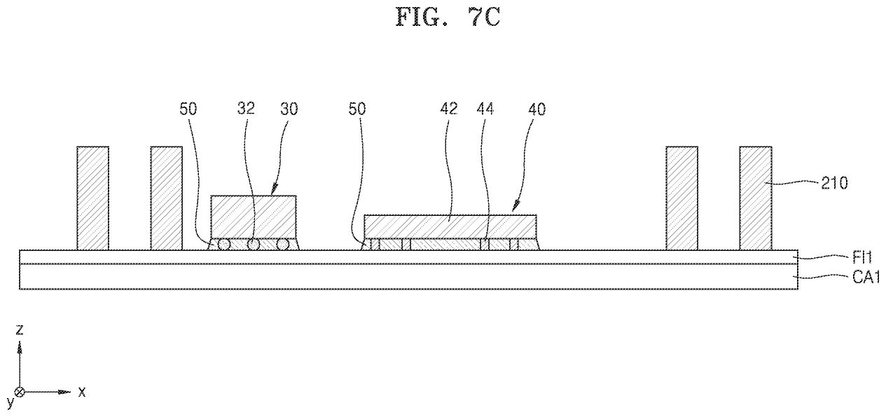

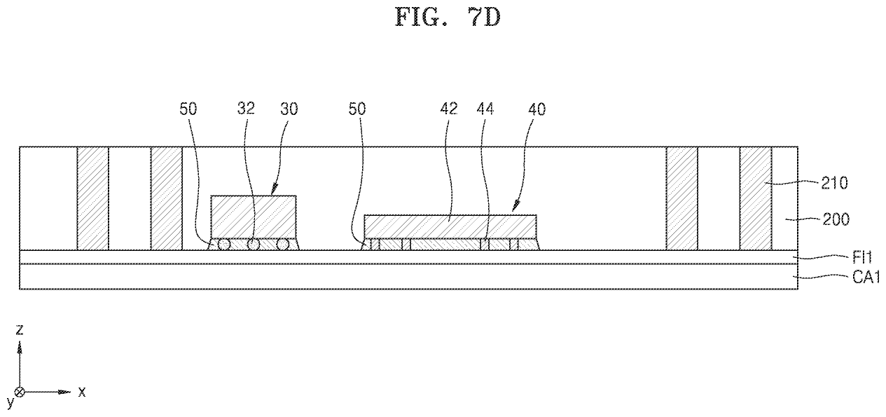

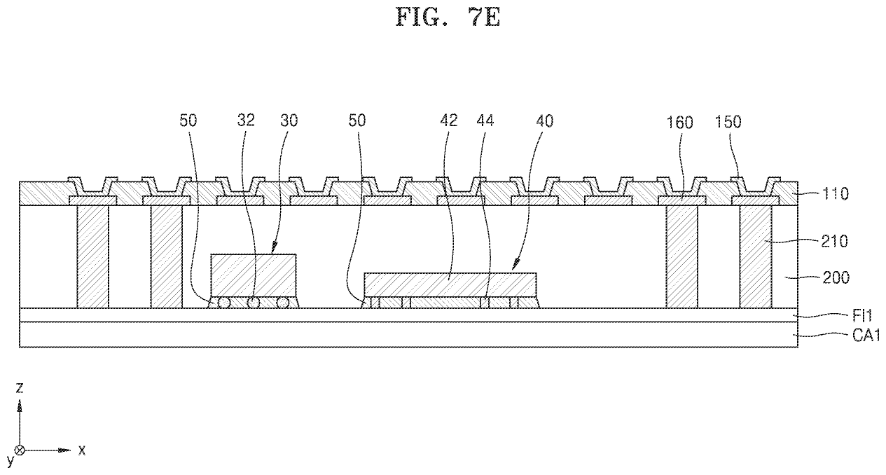

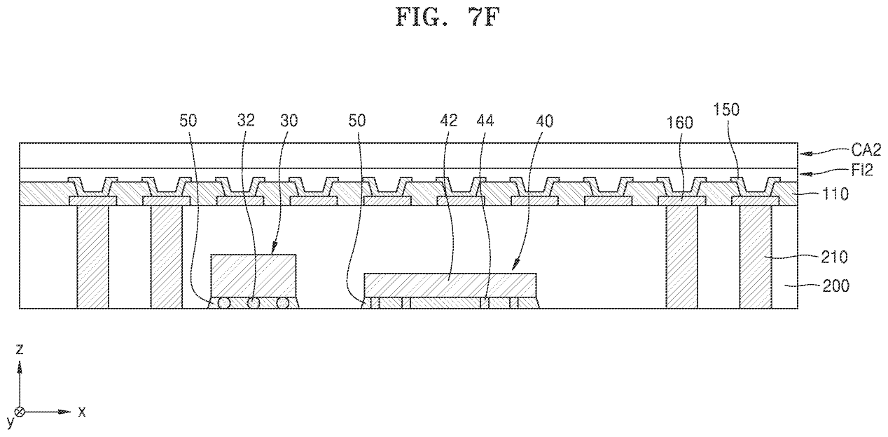

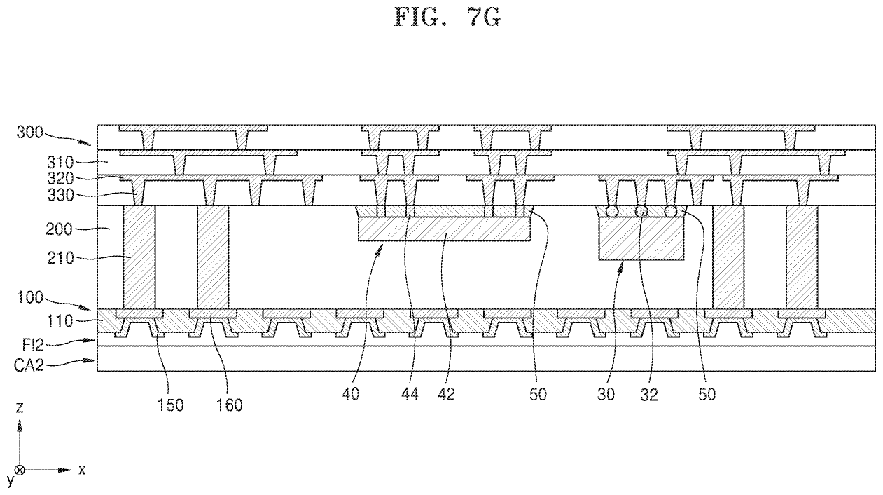

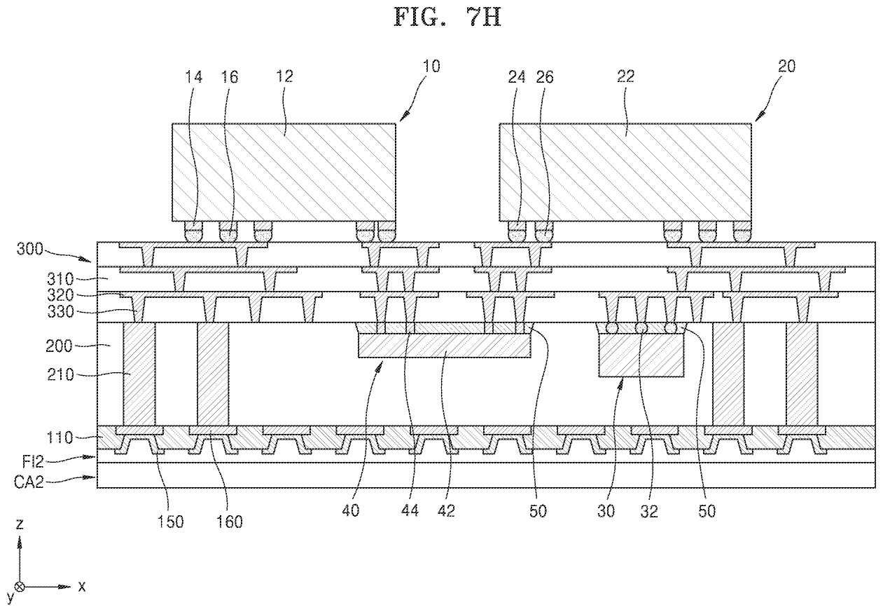

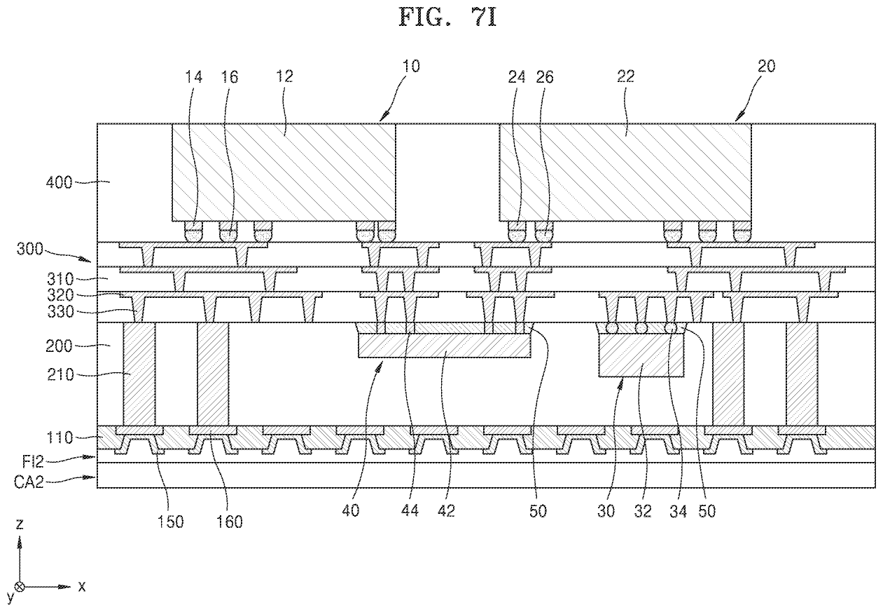

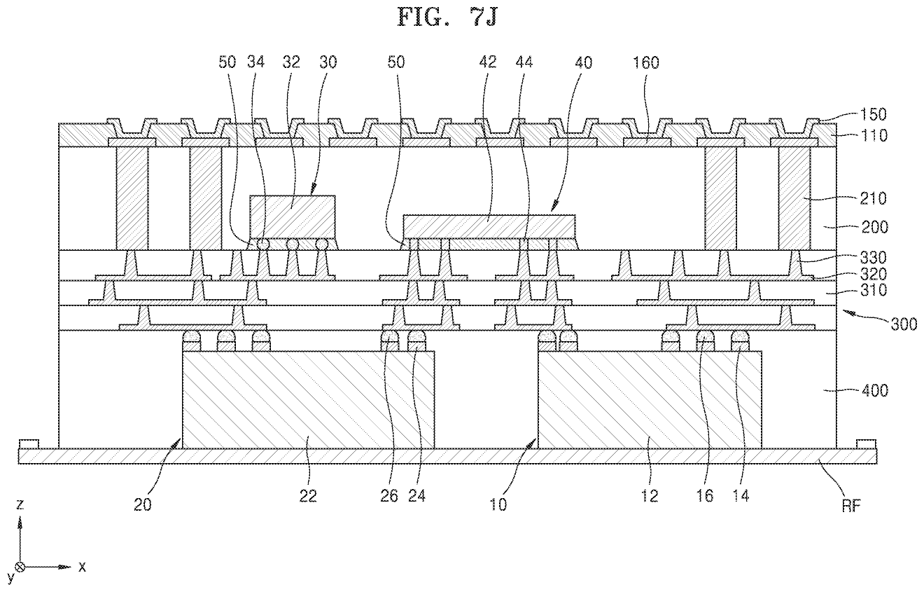

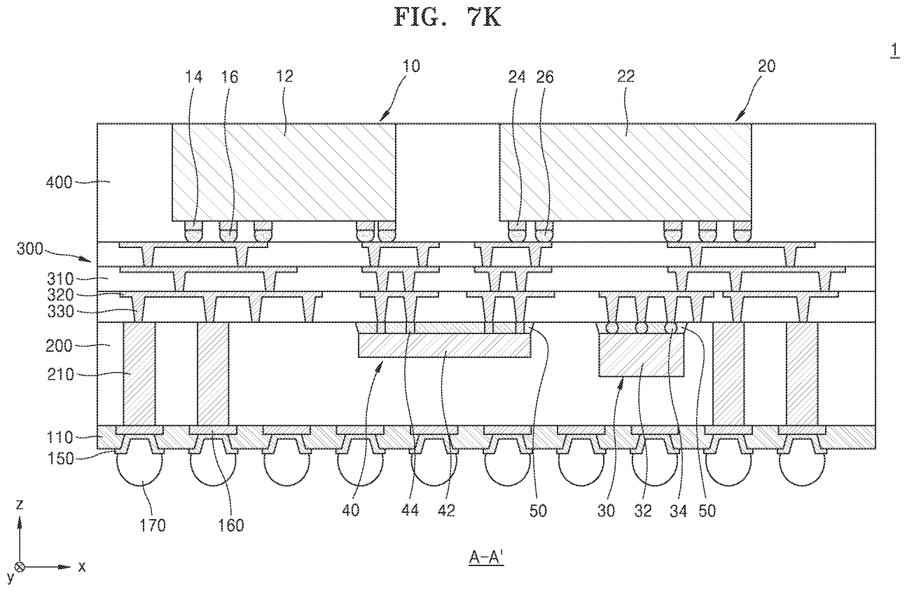

As described below, when the first device 30 and a first adhesive film FI1 in FIG. 7A is bonded to each other by soldering, the first device 30 may be electrically connected to the second redistribution structure 300 through the solder ball. In addition, when the first device 30 and the first adhesive film FI1 in FIG. 7A is bonded to each other by oxide bonding, the first device 30 may be electrically connected to the second redistribution structure 300 through the conductive pillar.

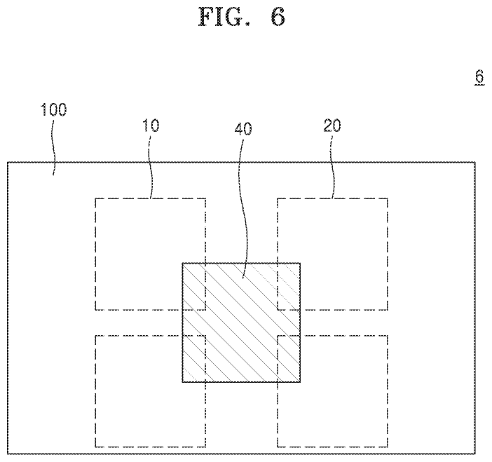

FIG. 6 is a plan view illustrating a semiconductor package according to an embodiment. For convenience of explanation, only a first semiconductor chip 10, a second semiconductor chip 20, a bridge chip 40, and a first redistribution structure 100 are illustrated in FIG. 6. The descriptions of FIG. 6 are given together with reference to FIGS. 1A and 1B.

Referring to FIG. 6, the bridge chip 40 may be positioned on a lower surface of the second redistribution structure 300. The bridge chip 40 may be provided as an electrical connection path between the first semiconductor chip 10 and the second semiconductor chip 20 on the second redistribution structure 300. For example, the first semiconductor chip 10 and the second semiconductor chip 20 may be electrically connected to each other through a bridge circuit in the bridge chip 40. As shown in FIG. 6, a pair of first semiconductor chips 10, which are spaced apart from each other in the horizontal direction (X-direction and/or Y-direction), and a pair of second semiconductor chips 20, which are spaced apart from each other in the horizontal direction (X-direction and/or Y-direction), may overlap at least a portion of the bridge chip 40 in the vertical direction (Z-direction), respectively.

However, embodiments are not limited thereto, and the first semiconductor chip 10, the second semiconductor chip 20, and the bridge chip 40 may be arranged in various ways. The bridge chip 40 may electrically connect a plurality of semiconductor chips with each other.

FIGS. 7A to 7K are cross-sectional views illustrating a method of fabricating a semiconductor package, according to an embodiment. The descriptions of FIGS. 7A to 7K are given together with reference to FIGS. 1A and 1B.

Referring to FIG. 7A, a first adhesive film FI1 may be attached onto a first carrier substrate CA1. For example, the first carrier substrate CA1 may include silicon (Si). The first adhesive film FI1 may include any material capable of fixing the first device 30, the bridge chip 40, and the conductive post 210. For example, the first adhesive film FI1 may include a thermosetting adhesive tape of which adhesion is weakened by heat treatment and an ultraviolet curable adhesive tape of which adhesion is weakened by ultraviolet irradiation.

Referring to FIG. 7B, a plurality of conductive posts 210 may be attached onto the first adhesive film FI1. For example, in a plan view, the conductive posts 210 may be arranged adjacent to a peripheral portion of the first adhesive film FI1. For example, the conductive post 210 may include a conductive material such as copper (Cu), aluminum (Al), silver (Ag), gold (Au), tungsten (W), titanium (Ti), and a combination thereof.

Referring to FIG. 7C, the first device 30 and the bridge chip 40 may be attached onto the first adhesive film FI1. In a plan view, the first device 30 and the bridge chip 40 may be attached adjacent to a central portion of the first adhesive film FI1. The first device 30, the bridge chip 40, and the conductive post 210 may be spaced apart from each other in the horizontal direction (X direction and/or Y direction).

The first device 30 may be attached to the first adhesive film FI1 by the third connection member 32, and the bridge chip 40 may be attached to the first adhesive film FI1 by the fourth connection member 44. The third connection member 32 and the fourth connection member 44 may be enclosed by the underfill layer 50.

For example, the first device 30 may be attached to the first adhesive film FI1 by a solder bonding, and the bridge chip 40 may be attached to the first adhesive film FI1 by oxide bonding. The third connection member 32 may include the solder ball, and the fourth connection member 44 may include the conductive pillar. However, embodiments are not limited thereto, and the bonding method for attaching the first device 30 and/or the bridge chip 40 to the adhesive film FI1 may be variously modified.

Referring to FIG. 7D, a first molding material layer may be formed on the first adhesive film FL1 in such a way that the first device 30, the bridge chip 40, and the plurality of conductive posts 210 are surrounded by the first molding material layer, and an upper portion of the first molding material layer may be removed, to thereby form the molding layer 200 on the first adhesive film FL1. A first molding material may be coated and cured on the first adhesive film FI1, to thereby form the first molding material layer.

The molding material may be the same as the material of the first molding layer 200 described with reference to FIG. 1B. After forming the first molding material layer, the upper portion of the first molding material layer and upper portions of the plurality of conductive posts 210 may be removed simultaneously by a grinding process. The first molding layer 200 may be formed by grinding the first molding material layer. When the formation of the first molding layer 200 is completed, an upper surface of the first molding layer 200 may be coplanar with upper surfaces of the plurality of conductive posts 210.

Referring to FIG. 7E, the first redistribution structure 100 may be formed on the first molding layer 200. The first redistribution structure 100 may include the passivation layer 110, the UBM layer 150, and the conductive layer 160. The exposed upper surface and the side surface of the conductive layer 160 may be covered by the passivation layer 110, and the lower surface of the conductive layer 160 may be partially exposed by the passivation layer 110. In addition, a portion of the upper surface of the passivation layer 110 may be covered by the UBM layer 150.

To form the first redistribution structure 100, the conductive layer 160 may be formed first on the first molding layer 200. The conductive layer 160 may be formed by a plating process. A seed layer may be additionally formed on the edge of the conductive layer 160 to prevent the metal material of the conductive layer 160 from diffusing into the passivation layer 110. After forming the conductive layer 160, a first operation of forming the passivation layer 110 covering the conductive layer 160 and having a via hole through which the conductive layer is partially exposed, a second operation of forming a UBM via filling the via hole and making contact with the conductive layer 160, and a third operation of forming a UBM pad covering the entire UBM via and a portion of the upper surface of the passivation layer 110 may be sequentially performed. The second operation of forming the UBM via and third operation of forming the UBM pad may include a plating process. In the first operation, the passivation layer 110 may be formed by, for example, a lamination process, a coating process, a chemical vapor deposition (CVD) process, a physical vapor deposition (PVD) process, and a combination thereof.

Referring to FIG. 7F, after removing the first adhesive film FI1 and the first carrier substrate CA1 from the first molding layer 200, a second carrier substrate CA2 attached with a second adhesive film FI2 may be attached to the passivation layer 110 and the UBM layer 150. For example, the second carrier substrate CA2 may include silicon (Si). In this case, the second adhesive film FI2 may be attached to the passivation layer 110 and the UBM pad. The second adhesive film FI2 and the second carrier substrate CA2 may be substantially the same as the first adhesive film FI1 and the first carrier substrate CA1, respectively.

Referring to FIG. 7G, after turning over the resultant structure shown in FIG. 7F, the second redistribution structure 300 may be formed on the first molding layer 200. The second redistribution structure 300 may include one or more redistribution insulating layers 310, the conductive line pattern 320, and the conductive via 330.

The redistribution insulating layers 310 may be stacked on the first molding layer 200 in the vertical direction (Z direction), and the conductive line pattern 320 may extend in the horizontal direction (X direction and/or Y direction) in the redistribution insulating layers 310. The conductive via 330 may be arranged in the redistribution insulating layer 310 and extend in the vertical direction (Z direction) in such a way that the conductive via 330 is electrically connected to at least one conductive line pattern 320.

A preliminary lowermost redistribution insulating layer may be formed on the first molding layer, and a plurality of via holes may be formed in the insulating layer by an exposure process. Then, the lowermost redistribution insulating layer 310 may be formed by forming the lowermost conductive line pattern 320 and the lowermost conductive via 330. The via hole may have a horizontal width reducing from an upper surface to a lower surface of the lowermost redistribution insulating layer 310. Thereafter, the redistribution insulating layers 310 and the conductive patterns may be alternately and repeatedly formed, to thereby form the second redistribution structure 300.

The third connection member 32 and the fourth connection member 44 may be electrically connected to the conductive line pattern 320 and/or the conductive via 330. In some embodiments, the conductive via 330 may have a tapered shape extending from an upper portion to a lower portion thereof and having a horizontal width reducing from the upper portion to the lower portion thereof.

Referring to FIG. 7H, a first semiconductor chip 10 and a second semiconductor chip 20 may be mounted on the second redistribution structure 300. The first semiconductor chip 10 may include the first substrate 12 and the first chip pad 14, and the second semiconductor chip 20 may include the second substrate 22 and the second chip pad 24.

The first connection member 16 may be formed between the first semiconductor chip 10 and the second redistribution structure 300, and the second connection member 26 may be formed between the second semiconductor chip 20 and the second redistribution structure 300. The first connection member 16 and the second connection member 26 may be electrically connected to the conductive line pattern 320 and/or the conductive via 330.

Referring to FIG. 7I, the second molding material layer may be formed on the second redistribution structure 300 to cover the first semiconductor chip 10 and the second semiconductor chip 20, and an upper portion of the second molding material layer may be removed, to thereby form the second molding layer 400. In an embodiment, a second molding material may be supplied and cured on the second redistribution structure 300, to thereby form the second molding material layer.

The second molding material may be the same as the material of the second molding layer 400 described with reference to FIG. 1B. After forming the second molding material layer, an upper portion of the second molding material layer, an upper portion of the first semiconductor chip 10, and/or an upper portion of the second semiconductor chip 20 may be grinded and removed. The second molding layer 400 may be formed by grinding the second molding material layer. When the formation of the second molding layer 400 is completed, the upper surface of the second molding layer 400, the upper surface of the first semiconductor chip 10, and the upper surface of the second semiconductor chip 20 may be coplanar with one another.

Referring to FIG. 7J, the second carrier substrate CA2 and the second adhesive film FI2 may be removed from the first redistribution structure 100, a ring frame RF may be attached to the upper surface of the second molding layer 400. An adhesive may be coated on an adhesive surface of the ring frame RF with which the second molding layer 400 makes contact, so that the ring frame RF may be attached to the first semiconductor chip 10, the second semiconductor chip 20, and the second molding layer 400. Then, the resultant structure in which the ring frame RF is attached to the second molding layer 400 may be turned over.

Referring to FIG. 7K, the external connection terminal 170 may be attached to the UBM layer 150, and then, the resultant structure may be turned over again in such a way that the upper surface of the first semiconductor chip 10 and the upper surface of the second semiconductor chip 20 face upwards in the vertical direction (Z direction). Thereafter, the ring frame RF in FIG. 7J may be removed to form the semiconductor package 1. The external connection terminal 170 may include, for example, a solder ball, a conductive bump, and a flip-chip connection structure having a grid array such as a pin grid array, a ball grid array, and a land grid array.

In FIGS. 7A to 7K, as an example, the first device 30 and the bridge chip 40 are formed on the carrier substrate CA1, and the second redistribution structure 300 is formed later. For example, FIGS. 7A to 7K are shown as an example that the semiconductor package 1 is fabricated by the chip-first process. However, embodiments are not limited thereto, and the second redistribution structure 300 may be formed first, and the first device 30 and the bridge chip 40 may be formed later on the second redistribution structure 300, so that the semiconductor package 1 may be formed by the chip-last process.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a first redistribution structure;
a second redistribution structure on the first redistribution structure;
a plurality of semiconductor chips on an upper surface of the second redistribution structure;
a bridge chip on a lower surface of the second redistribution structure; and
a first molding layer between the first redistribution structure and the second redistribution structure and adjacent to the bridge chip,
wherein the first molding layer is between the bridge chip and the first redistribution structure.

2. The semiconductor package of claim 1, further comprising
a plurality of conductive posts in the first molding layer and spaced apart from the bridge chip in a horizontal direction.

3. The semiconductor package of claim 1, further comprising:
a second molding layer on the second redistribution structure and adjacent to the plurality of semiconductor chips.

4. The semiconductor package of claim 3, wherein a height of the first molding layer is different from a height of the second molding layer in a vertical direction.

5. The semiconductor package of claim 1, further comprising:
a connection member between the bridge chip and the second redistribution structure; and
an underfill layer adjacent to the connection member.

6. The semiconductor package of claim 1, further comprising
a connection member between the bridge chip and the second redistribution structure,
wherein the connection member directly contacts the first molding layer.

7. The semiconductor package of claim 1, wherein the bridge chip is electrically connected to the first redistribution structure through the second redistribution structure.

8. The semiconductor package of claim 1, wherein the bridge chip overlaps at least two of the plurality of semiconductor chips in a vertical direction.

9. A semiconductor package comprising:
a first redistribution structure;
a second redistribution structure on the first redistribution structure;
a plurality of semiconductor chips on an upper surface of the second redistribution structure;
a bridge chip on a lower surface of the second redistribution structure;
a passive device spaced apart from the bridge chip in a horizontal direction and on the lower surface of the second redistribution structure;
a first molding layer between the first redistribution structure and the second redistribution structure and adjacent to the bridge chip and the passive device;
a plurality of conductive posts arranged in the first molding layer and spaced apart from the bridge chip and the passive device in the horizontal direction; and
a second molding layer on the upper surface of the second redistribution structure and adjacent to the plurality of semiconductor chips,
wherein the first molding layer is between the bridge chip and the first redistribution structure and between the passive device and the first redistribution structure.

10. The semiconductor package of claim 9, further comprising
a chiplet on the lower surface of the second redistribution structure and spaced apart from the bridge chip and the passive device in the horizontal direction.

11. The semiconductor package of claim 10, wherein the chiplet is spaced apart from the first redistribution structure in a vertical direction perpendicular to the horizontal direction.

12. The semiconductor package of claim 9, wherein a height of the passive device, a height of the bridge chip, and a height of the chiplet in a vertical direction are different from one another.

13. The semiconductor package of claim 9, wherein the first redistribution structure comprises:
a passivation layer;
an under bump metallurgy (UBM) layer on a portion of a lower surface of the passivation layer; and
a conductive layer in contact with the UBM layer and exposed to an upper surface opposite to the lower surface of the passivation layer.

14. The semiconductor package of claim 9, wherein a height of the first molding layer is lower than a height of the second molding layer in a vertical direction.

15. The semiconductor package of claim 9, wherein a height of the passive device is different from a height of the bridge chip in a vertical direction.

16. A semiconductor package comprising:
a first redistribution structure comprising a passivation layer, an under bump metallurgy (UBM) layer on a portion of a lower surface of the passivation layer, and a conductive layer in contact with the UBM layer and exposed to an upper surface opposite to the lower surface of the passivation layer;
a second redistribution structure comprising at least one redistribution insulating layer, a plurality of conductive line patterns in the at least one redistribution insulating layer and extending in a horizontal direction, and a plurality of conductive vias in the at least one redistribution insulating layer and extending in a vertical direction perpendicular to the horizontal direction;
a plurality of semiconductor chips on an upper surface of the second redistribution structure;
a bridge chip on a lower surface of the second redistribution structure and electrically connecting at least two of the plurality of semiconductor chips;
a passive device on the lower surface of the second redistribution structure and spaced apart from the bridge chip in the horizontal direction;
a first molding layer between the first redistribution structure and the second redistribution structure and adjacent to a side surface of the bridge chip and a side surface of the passive device;
a plurality of conductive posts in the first molding layer and spaced apart from the bridge chip and the passive device in the horizontal direction; and
a second molding layer on the upper surface of the second redistribution structure and adjacent to the plurality of semiconductor chips,
wherein the first molding layer is between the bridge chip and the first redistribution structure and between the passive device and the first redistribution structure.

17. The semiconductor package of claim 16, wherein each of the plurality of conductive vias has a tapered shape of which a horizontal width decreases away from the plurality of semiconductor chips.

18. The semiconductor package of claim 16, further comprising:
a passive device connection member between the passive device and the second redistribution structure; and
a bridge chip connection member between the bridge chip and the second redistribution structure,
wherein each of the passive device connection member and the bridge chip connection member comprises at least one of a solder ball and a conductive pillar.

19. The semiconductor package of claim 16, wherein an upper surface of the second molding layer and upper surfaces of the plurality of semiconductor chips are coplanar.

20. The semiconductor package of claim 16, wherein a horizontal width of each of the plurality of conductive posts is less than a horizontal width of the conductive layer.
